(19) United States
(12) Patent Application Publication
(10) Pub. No.: US 2015/0090491 A1
(43) Pub. Date: Apr. 2, 2015

(54) ELECTRICAL CABLE ASSEMBLY HAVING AN ELECTRICAL SHIELD

(71) Applicant: Tyco Electronics Corporation, Berwyn, PA (US)

(72) Inventors: Steven David Dunwoody, Middletown, PA (US); Richard James Long, Columbia, PA (US); James Russell Renzas, San Bruno, CA (US)

(73) Assignee: Tyco Electronics Corporation, Berwyn, PA (US)

(21) Appl. No.: 14/044,080

(22) Filed: Oct. 2, 2013

(51) Int. Cl. H05K 9/00; H02G 15/02

(52) U.S. Cl. CPC H05K 9/009; H02G 15/02
USPC 174/74 R; 174/102 R

(57) ABSTRACT

An electrical cable assembly includes an electrical cable extending a length from a first cable end to an opposite second cable end. The electrical cable includes at least one electrical wire. A first electrical connector is terminated to the first cable end of the electrical cable. A second electrical connector is terminated to the second cable end of the electrical cable. The assembly includes an electrical cable shield that includes a metallized fabric body that extends around the electrical cable along the length of the electrical cable. The metallized fabric body extends a length along the length of the electrical cable from a first shield end to a second shield end of the metallized fabric body. The first shield end of the metallized fabric body is dressed over the first electrical connector. The second shield end of the metallized fabric body is dressed over the second electrical connector.

### BACKGROUND OF THE INVENTION

The subject matter herein relates generally to electrical cables, and more particularly to electrical shields for electrical cables.

Many electrical cables include electrical shields that provide electrical shielding for one or more electrical wires of the cable. Examples of known electrical cable shields include electrically conductive foils and braids of electrically conductive strands of material that surround the electrical wire(s) of the electrical cable. The shielding provided by electrical cable shields may reduce electromagnetic interference (EMI) emissions from the electrical cable or an assembly of the electrical cable and an electrical connector that terminates the electrical cable. Such EMI emissions may harm the signal integrity and/or electrical performance of neighboring electrical devices, for example. Moreover, government regulations may require that EMI emissions be contained to a predetermined level.

Known electrical cable shields are not without disadvantages. For example, it is difficult to install electrical cable shields after an electrical connector has been terminated to the electrical cable. Moreover, and for example, at least some known electrical cable shields may be inadequate because of the increasing signal speeds being transmitted through electrical cables and the electrical connectors terminated thereto. One example of a problem caused by such increasing signal speeds is that the assembly of an electrical cable and an electrical connector may leak EMI above certain signal speeds, such as above approximately 10 gigahertz (GHz), at the interface between the electrical cable shield and the electrical connector. For example, it may be difficult to terminate (i.e., electrically and/or mechanically connect) an electrically conductive foil to the electrical connector without tearing the foil. Electrically conductive foils thus may tend to leak EMI at the interface between the electrically conductive foil and the electrical connector. Moreover, and for example, while electrically conductive braids can be terminated to an electrical connector by being dressed over a ferrule of the electrical connector, such cable braids may be especially susceptible to EMI leakage at the interface between the cable braid and the ferrule because of the flare of the cable braid over the ferrule.

Accordingly, there is a need for an electrical cable shield that reduces EMI emissions.

### BRIEF DESCRIPTION OF THE INVENTION

In an embodiment, an electrical cable assembly includes an electrical cable extending a length from a first cable end to an opposite second cable end. The electrical cable includes at least one electrical wire. A first electrical connector is terminated to the first cable end of the electrical cable. A second electrical connector is terminated to the second cable end of the electrical cable. The assembly includes an electrical cable shield that includes a metallized fabric body that extends around the electrical cable along the length of the electrical cable. The metallized fabric body extends a length along the length of the electrical cable from a first shield end to a second shield end of the metallized fabric body. The first shield end of the metallized fabric body is dressed over the first electrical connector. The second shield end of the metallized fabric body is dressed over the second electrical connector.

In an embodiment, an electrical cable assembly includes an electrical cable extending a length from a first cable end to an opposite second cable end. The electrical cable includes at least one electrical wire. The assembly includes an electrical cable shield having a metallized fabric body that extends around the electrical cable along the length of the electrical cable between the first and second cable ends. The metallized fabric body extends a length along the length of the electrical cable from a first shield end to a second shield end of the metallized fabric body. The metallized fabric body has opposite first and second edges that extend along the length of the metallized fabric body from the first shield end to the second shield end. The first and second edges are sewed together with an electrically conductive thread.

In an embodiment, an electrical cable assembly includes an electrical cable extending a length from a first cable end to an opposite second cable end. The electrical cable includes at least one electrical wire. The assembly includes an electrical cable shield having a metallized fabric body that extends around the electrical cable along the length of the electrical cable from the first cable end to the second cable end.

### BRIEF DESCRIPTION OF THE DRAWINGS

FIG. 1 is a perspective view of an embodiment of an electrical cable assembly.

FIG. 2 is a perspective view of a portion of the electrical cable assembly shown in FIG. 1.

FIG. 3 is a perspective view of an embodiment of an electrical cable shield of the electrical cable assembly shown in FIGS. 1 and 2.

FIG. 4 is another perspective view of the electrical cable assembly shown in FIGS. 1 and 2 illustrating the electrical cable shield shown in FIG. 3 installed over an embodiment of an electrical cable of the assembly.

### DETAILED DESCRIPTION OF THE INVENTION

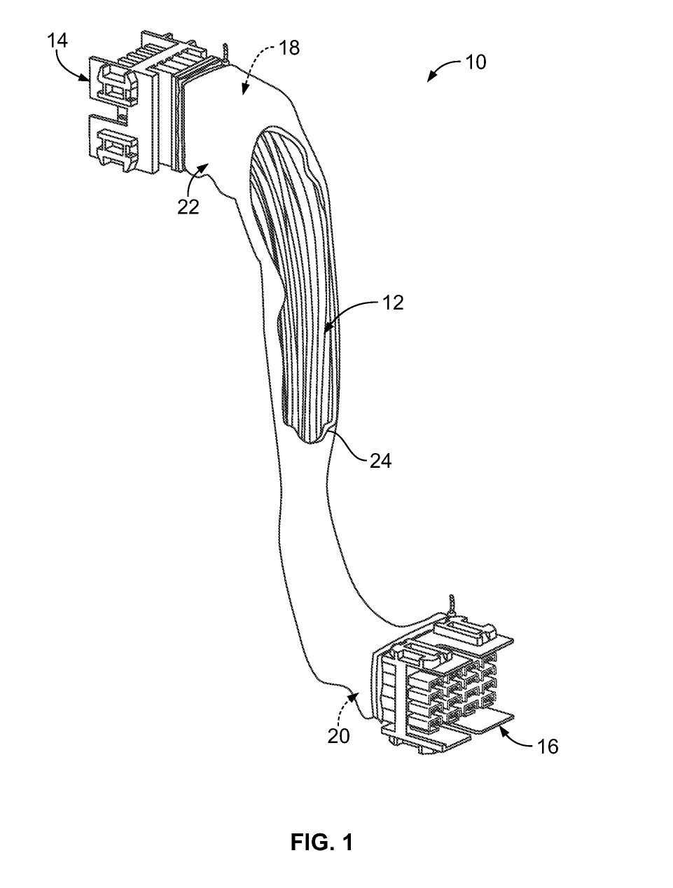

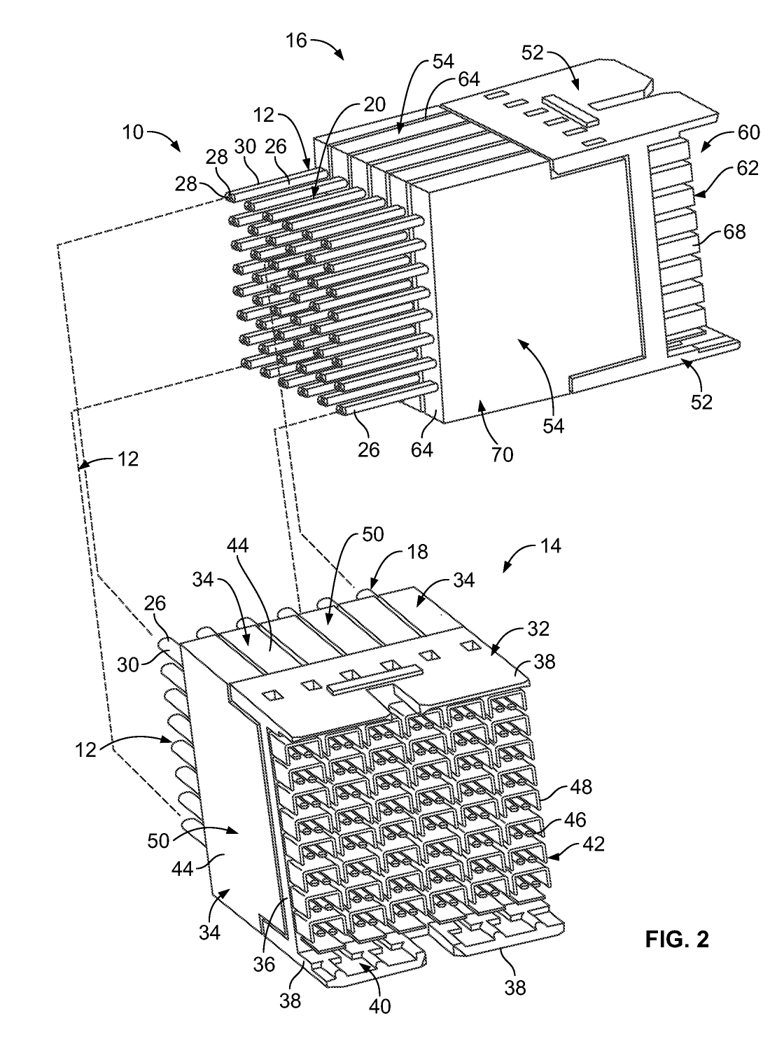

FIG. 1 is a perspective view illustrating an embodiment of an electrical cable assembly 10. The assembly 10 includes an electrical cable 12, an electrical connector 14 terminated to the electrical cable 12, and another electrical connector 16 terminated to the electrical cable 12. The electrical cable 12 extends a length from an end 18 to an opposite end 20. The ends 18 and 20 of the cable are also shown in FIG. 2. As can be seen in FIG. 1, the electrical connector 14 is terminated (i.e., electrically and mechanically connected) to the end 18 of the electrical cable 12, while the electrical connector 16 is terminated to the end 20 of the electrical cable 12. Accordingly, the electrical cable 12 extends between, and interconnects, the electrical connectors 14 and 16. Each of the electrical connectors 14 and 16 may be referred to herein as a “first” and/or a “second” electrical connector. Each of the ends 18 and 20 of the electrical cable 12 may be referred to herein as a “first cable” end and/or a “second cable” end.

The electrical cable assembly 10 includes an electrical cable shield 22 that extends around the electrical cable 12. A portion of the electrical cable shield 22 has been broken away from FIG. 1 to illustrate the underlying electrical cable 12. As will be described in more detail below, the electrical cable shield 22 includes a metallized fabric body 24 for reducing EMI emissions from the assembly 10.

FIG. 2 is a perspective view of a portion of the electrical cable assembly 10. Specifically, the electrical cable shield 22 has been removed from the assembly 10 in FIG. 2 to better illustrate the electrical cable 12 and the electrical connectors 14 and 16. The electrical cable 12 includes one or more electrical wires 26. Each electrical wire 26 includes one or more electrical conductors 28. Optionally, each electrical wire 26 is individually insulated and/or individually shielded. Moreover, each electrical conductor 28 of each electrical wire 26 is optionally individually insulated and/or individually shielded.

The electrical cable 12 may include any number of the electrical wires 26, and each electrical wire 26 may include any number of electrical conductors 28. In the illustrated embodiment, each electrical wire 26 is a twin axial wire having two signal conductors 28 contained within a common jacket 30. The signal conductors 28 convey differential signals and are shielded (e.g., individually or with an electrically conductive shield, not shown, of the corresponding electrical wire 26). Other types of electrical wires 26 may be provided in other embodiments. For example, the electrical wires 26 may be coaxial wires having a single signal conductor 28 therein.

Optionally, the electrical cable 12 includes an electrically insulative jacket (not shown) that extends around the electrical wires 26. Moreover, the electrical cable 12 optionally includes an electrically conductive shield (not shown, and which may be referred to herein as a “second” electrical cable shield) that extends around the electrical wires 26 between the electrically insulative jacket and the electrical wires 26. Examples of such an electrically conductive shield that extends around the electrical wires 26 between the electrically insulative jacket and the electrical wires 26 include a conventional electrically conductive foil and a conventional electrically conducive braid.

The electrical connectors 14 and 16 may each be any type of electrical connector. In the illustrated embodiment, the electrical connectors 14 and 16 are STRADA Whisper header connectors, commercially available from TE Connectivity, Harrisburg, Pa. In an embodiment, the electrical connector 14 and/or 16 is a high speed differential pair cable connector that includes a plurality of differential pairs of conductors mated at a common mating interface. The differential conductors may be shielded along the signal paths thereof to reduce noise, crosstalk, and/or other interference along the signal paths of the differential pairs. For example, in the illustrated embodiment, the electrical connector 14 includes a housing 32 that holds a plurality of contact modules 34. The housing 32 includes a base wall 36 and shroud walls 38 extending from the base wall 36 to define a mating cavity 40 configured to receive a complementary mating connector (not shown) with which the electrical connector 14 is configured to mate. The shroud walls 38 guide mating of the electrical connector 14 with the complementary mating connector.

Each of the contact modules 34 includes a plurality of cable assemblies 42 held by a support body 44. Each cable assembly 42 includes a pair of signal contacts 46 terminated to corresponding signal conductors 28 of the corresponding electrical wire 26. Each cable assembly 42 also includes a ground shield 48 providing shielding for the signal contacts 46. In the illustrated embodiment, the ground shield 48 peripherally surrounds the signal contacts 46 along the entire length of the signal contacts 46 to ensure that the signal paths are electrically shielded.

The support body 44 provides support for the cable assemblies 42. The electrical wires 26 extend into the support body 44 such that the support body 44 supports a portion of the electrical wires 26. The support body 44 may provide strain relief for the electrical wires 26. Optionally, the support body 44 may be fabricated from a plastic and/or other dielectric material. In addition or alternatively, the support body 44 may be fabricated from one or more metal materials. At least a portion of the support body 44 is optionally electrically conductive to provide electrical shielding for the electrical wires 26 and/or the signal contacts 46. For example, a majority or an approximate entirety of the support body 44 may be fabricated from one or more metal material to provide such electrical shielding. In other embodiments, the support body 44 may be a metalized dielectric material (e.g., a dielectric material plated or otherwise coated with a metal material, a dielectric material filled with a metal material, and/or the like) to provide electrical shielding for the electrical wires 26 and/or signal contacts 46. In an embodiment, the support body 44 includes a metal plate (not shown) that is electrically connected to each ground shield 48 (to electrically common each ground shield 48) and is surrounded by a dielectric material (e.g., an overmold and/or the like).

As can be seen in FIG. 2, multiple contact modules 34 are loaded into the housing 32. The support bodies 44 of the contact modules 34 define a backshell 50 of the electrical connector 14. In the illustrated embodiment, the housing 32 holds the contact modules 34 in parallel such that the cable assemblies 42 are aligned in columns. Any number of contact modules 34 may be held by the housing 32 depending on the particular application. When the contact modules 34 are stacked in the housing 32, the cable assemblies 42 may also be aligned in rows. The backshell 50 may be referred to herein as a “first” and/or a “second” backshell.

Optionally, the electrical connectors 14 and 16 are substantially identical to one another. In the illustrated embodiment, the electrical connector 16 is substantially identical to the electrical connector 14. Specifically, the electrical connector 16 includes a housing 52 that holds a plurality of contact modules 54. The housing 52 includes a mating cavity 60 that is configured to receive a complementary mating connector (not shown) with which the electrical connector 16 is configured to mate.

Each of the contact modules 54 includes a plurality of cable assemblies 62 held by a support body 64. Each cable assembly 62 includes a pair of signal contacts (not shown) terminated to corresponding signal conductors 28 of the corresponding electrical wire 26. Each cable assembly 62 also includes a ground shield 68 providing shielding for the signal contacts. In the illustrated embodiment, the ground shield 68 peripherally surrounds the signal contacts along the entire length of the signal contacts to ensure that the signal paths are electrically shielded.

The support body 64 provides support for the cable assemblies 62. The electrical wires 26 extend into the support body 64 such that the support body 64 supports a portion of the electrical wires 26. The support body 64 may provide strain relief for the electrical wires 26. Optionally, the support body 64 may be fabricated from a plastic and/or other dielectric material. In addition or alternatively, the support body 64 may be fabricated from one or more metal materials. At least a portion of the support body 64 is optionally electrically conductive to provide electrical shielding for the electrical wires 26 and/or the signal contacts. For example, a majority or an approximate entirety of the support body 64 may be fabricated from one or more metal material to provide such electrical shielding. In other embodiments, the support body 64 may be a metalized dielectric material (e.g., a dielectric material plated or otherwise coated with a metal material, a dielectric material filled with a metal material, and/or the like) to provide electrical shielding for the electrical wires 26 and/or signal contacts. In an embodiment, the support body 64 includes a metal plate (not shown) that is electrically connected to each ground shield 68 (to electrically common each ground shield 68) and surrounded by a dielectric material (e.g., an overmold and/or the like).

The support bodies 64 of the contact modules 54 define a backshell 70 of the electrical connector 16. In the illustrated embodiment, the housing 52 holds the contact modules 54 in parallel such that the cable assemblies 62 are aligned in columns. Any number of contact modules 54 may be held by the housing 52 depending on the particular application. When the contact modules 54 are stacked in the housing 52, the cable assemblies 62 may also be aligned in rows. The backshell 70 may be referred to herein as a “first” and/or a “second” backshell.

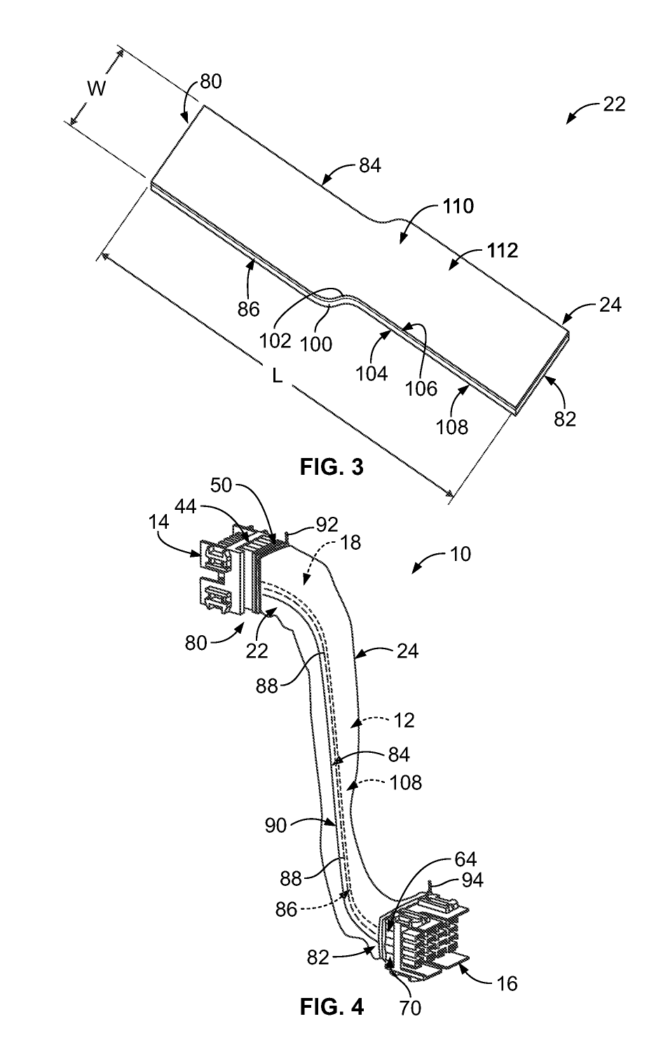

FIG. 3 is a perspective view of an embodiment of the electrical cable shield 22. The electrical cable shield 22 includes the metallized fabric body 24. The metallized fabric body 24 extends a length L from an end 80 to an opposite end 82. The metallized fabric body 24 extends a width W from an edge 84 to an opposite edge 86. As can be seen in FIG. 3, the edges 84 and 86 extend along the length L of the metallized fabric body 24 from the end 80 to the end 82 of the metallized fabric body 24. Each of the ends 80 and 82 may be referred to herein as a “first shield end” and/or a “second shield end”. Each of the edges 84 and 86 may be referred to herein as a “first edge” and/or a “second edge”.

The metallized fabric body 24 of the electrical cable shield 22 is shown in FIG. 3 in an unwrapped configuration. As will be described below, the metallized fabric body 24 is configured to be wrapped around the electrical cable 12 such that the length L of the metallized fabric body 24 extends along the length of the electrical cable 12. The edges 84 and 86 of the metallized fabric body 24 can be connected together or overlapped such that the metallized fabric body 24 extends around the entirety of the circumference of the electrical cable 12.

The metallized fabric body 24 includes a structure having at least one layer 100 of fabric and at least one layer 102 of metal. The metallized fabric body 24 may include any number of layers 100 and 102 overall, and may include any number of fabric layers 100 and any number of metal layers 102. In the illustrated embodiment, the metallized fabric body 24 includes a single fabric layer 100 and a single metal layer 102. The fabric layer 100 includes opposite sides 104 and 106. The metal layer 102 extends on the side 106 of the fabric layer 100. The metallized fabric body 24 may include one or more other layers (not shown) in addition to the fabric layer(s) 100 and the metal layer(s) 102.

The fabric layer(s) 100 and the metal layer(s) 102 of the metallized fabric body 24 may be arranged relative to each other in any relative arrangement. In the illustrated embodiment, the fabric layer 100 defines an interior side 108 of the metallized fabric body 24, while the metal layer 102 defines an exterior side 110 of the metallized fabric body 24. Specifically, the side 104 of the fabric layer 100 defines the interior side 108, and a side 112 of the metal layer 102 defines the exterior side 110 of the metallized fabric body 24. The interior side 108 of the metallized fabric body 24 is configured to face the electrical cable 12 (FIGS. 1, 2, and 4) when the electrical cable shield 22 is installed over the electrical cable 12. The exterior side 110 of the metallized fabric body 24 is configured to face away from the electrical cable 12 when the electrical cable shield 22 is installed over the electrical cable 12.

As discussed above, the metallized fabric body 24 is not limited to the illustrated arrangement and number of the fabric and metal layers 100 102, respectively. For example, in some other embodiments, the fabric layer 100 defines the exterior side 110 of the metallized fabric body 24 and the metal layer 102 defines the interior side 108 of the metallized fabric body 24. In another embodiment, the metallized fabric body 24 includes two fabric layers 100 (that define the interior side 108 and the exterior side 110) and one or more metal layers 102 sandwiched between the two fabric layers 100. Another embodiment of the metallized fabric body 24 includes two metal layers 102 (that define the interior side 108 and the exterior side 110) and one or more fabric layers 100 sandwiched between the two metal layers 102. In yet another embodiment, the metallized fabric body 24 includes an alternating pattern of fabric layers 100 and metal layers 102. In still other embodiments, the metallized fabric body 24 includes one or more other layers (not shown) in addition to the fabric layer(s) 100 and the metal layer(s) 102. For example, the metallized fabric body 24 may include one or more electrically insulative layers (not shown) that defines the exterior side 110 of the metallized fabric body 24 (e.g., extends over the outermost layer 100 or 102), for example to prevent electrical shorting and/or to electrically insulate the exterior side 110. Moreover, and for example, the metallized fabric body 24 may include one or more electrically insulative layers (not shown) that defines the interior side 108 of the metallized fabric body 24 (e.g., extends over the innermost layer 100 or 102), for example to prevent electrical shorting. Another example includes providing the metallized fabric body 24 with one or more aesthetic and/or tactile (e.g., decorative, textured, and/or the like) layers that defines the exterior side 110 of the body 24, for example to facilitate improving the look and/or feel of the electrical cable 12.

The number and/or arrangement of the metal layer(s) 102, the fabric layer(s) 100, and the other layer(s) of the metallized fabric body 24 may be selected to: (1) provide a predetermined amount of electrical shielding; and/or (2) enable one or more metal layers 102 to electrically connect to the electrical connectors 12 and/or 14 (FIGS. 1, 2, and 4).

Each fabric layer 100 of the metallized fabric body 24 may be fabricated from any fabric, such as, but not limited to, nylon, polyester, cotton, wool, a natural fiber, a synthetic fiber, and/or the like. Each metal layer 102 of the metallized fabric body 24 may be fabricated from any metal, such as, but not limited to, aluminum, steel, tin, nickel, silver, gold, copper, a metal alloy, and/or the like. The materials used to fabricate the fabric layer(s) 100 and/or the metal layer(s) 102 of the metallized fabric body 24 may be selected to provide the metallized fabric body 24 with a predetermined flexibility. The materials used to fabricate the metal layer(s) 102 of the metallized fabric body 24 may be selected to enable the metallized fabric body 24 to provide a predetermined amount of electrical shielding and/or to provide the metallized fabric body 24 with a predetermined electrical conductivity. In an embodiment, the metallized fabric body 24 is woven or non-woven Flectron™ metalized fabric, which is commercially available from Laird Technologies.

FIG. 4 is another perspective view of the electrical cable assembly 10 illustrating the electrical cable shield 22 installed over the electrical cable 12. The metallized fabric body 24 has been wrapped around the electrical cable 12 such that the length L (FIG. 3) of the metallized fabric body 24 extends along the length of the electrical cable 12. The metallized fabric body 24 extends around the circumference of the electrical cable 12 along at least a portion of the length of the electrical cable 12. The metallized fabric body 24 may be wrapped around the electrical cable 12 relatively loosely such that there is an air gap between the interior side 108 of the metallized fabric body 24 and the electrical cable 12 along at least a portion of the length of the electrical cable 12. Such an optional air gap can be seen in FIG. 1. In embodiments wherein the electrical cable 12 includes an electrically insulative jacket (not shown) that extends around the electrical wires 26 (FIG. 2) (and/or optionally an electrically conductive shield that extends around the electrical wires 26 between the electrically insulative jacket and the electrical wires 26), the metallized fabric body 24 extends around the electrically insulative jacket and/or the electrically conductive shield.

In the illustrated embodiment, the edges 84 and 86 of the metallized fabric body 24 have been connected together such that the metallized fabric body 24 extends around the entirety of the circumference of the electrical cable 12 along at least a portion of the length of the electrical cable 12. The edges 84 and 86 may be connected together using any suitable method, means, structure, and/or the like to hold the metallized fabric body 24 in the position wrapped around the electrical cable 12, such as, but not limited to, an adhesive, by sewing the edges 84 and 86 together, a zip tie, a band, a rubber band, a heat recoverable ring, a clamp, a hose clamp, safety wire, and/or the like. In the illustrated embodiment, the edges 84 and 86 are sewn together using a thread 88 to connect the edges together. The edges 84 and 86 may be sewn together using any type of thread 88, such as, but not limited to, a non-electrically conductive thread, an electrically conductive thread, and/or the like. Sewing the edges 84 and 86 together using an electrically conductive thread 88 may facilitate containing EMI emissions from leaking through a seam 90 of the electrical cable shield 22. In alternative to being connected together at the edges 84 and 86, the edges 84 and 86 may be overlapped by any amount to form any whole or partial number of layers of wrappings around the electrical cable 12. The edges 84 and 86 may be held as overlapped using any suitable method, means, structure, and/or the like, such as, but not limited to, an adhesive, by sewing portions of the metallized fabric together with an electrically conductive or non-electrically conductive thread (e.g., the thread 88), a zip tie, a band, a rubber band, a heat recoverable ring, a clamp, a hose clamp, safety wire, and/or the like.

The metallized fabric body 24 of the electrical cable shield 22 may extend around the electrical cable 12 along any amount and any portion(s) of the length of the electrical cable 12. In the illustrated embodiment, the metallized fabric body 24 extends around the circumference of the electrical cable 12 along an approximate entirety of the length of the electrical cable 12 from the electrical connector 14 to the electrical connector 16. Optionally, the end 80 of the metallized fabric body 24 is dressed over the electrical connector 14. The opposite end 82 of metallized fabric body 24 is optionally dressed over the electrical connector 16. Specifically, in the illustrated embodiment, the end 80 of the metallized fabric body 24 is dressed over the backshell 50 of the electrical connector 14, and the end 82 is dressed over the backshell 70 of the electrical connector 16. As can be seen in FIG. 4, the backshells 50 and 70 include fittings having non-circular profiles in the illustrated embodiment. Accordingly, in the illustrated embodiment, the ends 80 and 82 of the metallized fabric body 24 are dressed over the non-circular profiles of the backshells 50 and 70, respectively. But, the ends 80 and 82 of the metallized fabric body 24 may each be dressed over a fitting of an electrical connector having any other shape.

Each of the ends 80 and 82 of the metallized fabric body 24 may be held on (i.e., as dressed over) the backshells 50 and 70, respectively, using any suitable method, means, structure, and/or the like, such as, but not limited to, an adhesive, a zip tie, a band, a rubber band, a heat recoverable ring, a clamp, a hose clamp, safety wire, and/or the like. In the illustrated embodiment, the ends 80 and 82 are held on the respective backshells 50 and 70 using zip ties 92 and 94, respectively.

Optionally, the end 80 and/or 82 of the metallized fabric body 24 is electrically connected to the respective electrical connector 14 and/or 16. Specifically, the end 80 and/or the end 82 may be dressed over the respective backshell 50 and/or 70 such that the end 80 and/or 82 is electrically connected to the optional electrical shield provided by the support bodies 44 and/or 64 of the respective backshell 50 and/or 70. The metallized fabric body 24 may thereby form part of a ground and/or shielding circuit of the electrical cable assembly 10. The ends 80 and 82 may each be electrically connected to the respective electrical connector 14 and 16 using any suitable method, means, structure, and/or engagement. For example, the interior side 108 of the metallized fabric body 24 may engage in physical contact with an exterior surface of the backshell 50 and/or 70 that defines an electrically conductive portion of the backshell 50 and/or 70.

As should be apparent from FIGS. 1-4, the metallized fabric body 24 may be installed around the electrical cable 12 after the electrical connectors 14 and/or 16 have been terminated to the electrical cable 12. The electrical cable shield 22 may therefore be more easily installed to the electrical cable 12 (and optionally on the electrical connectors 14 and 16) than at least some known electrical cable shields.

When installed on the electrical cable 12 and the electrical connectors 14 and 16 as shown in FIGS. 1 and 4, the electrical cable shield 22 is configured to provide electrical shielding along the length of the electrical cable 12 (and optionally along the backshells 50 and/or 70) that facilitates reducing EMI emissions from the electrical cable assembly 10.

The embodiments described and/or illustrated herein may provide an electrical cable shield that reduces EMI emissions from an electrical cable assembly. For example, the embodiments described and/or illustrated herein may provide an electrical cable shield that reduces EMI emissions from leaking through an interface between the electrical cable shield and an electrical connector that terminates the electrical cable.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

What is claimed is:

1. An electrical cable assembly comprising:
an electrical cable extending a length from a first cable end to an opposite second cable end, the electrical cable comprising at least one electrical wire;
a first electrical connector terminated to the first cable end of the electrical cable;
a second electrical connector terminated to the second cable end of the electrical cable; and
an electrical cable shield comprising a metallized fabric body that extends around the electrical cable along the length of the electrical cable, the metallized fabric body extending a length along the length of the electrical cable from a first shield end to a second shield end of the metallized fabric body, the first shield end of the metallized fabric body being dressed over the first electrical connector, the second shield end of the metallized fabric body being dressed over the second electrical connector.

2. The electrical cable assembly of claim 1, wherein the first and second electrical connectors comprise first and second backshells, respectively, the first shield end of the metallized fabric body being dressed over the first backshell of the first electrical connector, the second shield end of the metallized fabric body being dressed over the second backshell of the second electrical connector.

3. The electrical cable assembly of claim 1, wherein the metallized fabric body of the electrical cable shield comprises opposite first and second edges that extend along the length of the metallized fabric body from the first shield end to the second shield end, the first and second edges being sewed together with an electrically conductive thread.

4. The electrical cable assembly of claim 1, wherein at least one of the first shield end of the metallized fabric body is held on the first electrical connector or the second shield end of the metallized fabric body is held on the second electrical connector using at least one of a zip tie, a band, a rubber band, a heat recoverable ring, a clamp, a hose clamp, safety wire, or an adhesive.

5. The electrical cable assembly of claim 1, wherein the metallized fabric body of the electrical cable shield is configured to be installed around the electrical cable after the first and second electrical connectors have been terminated to the first and second cable ends, respectively, of the electrical cable.

6. The electrical cable assembly of claim 1, wherein the metallized fabric body of the electrical cable shield comprises a fabric layer and a metal layer that extends on the fabric layer, the fabric layer being fabricated from at least one of nylon or polyester.

7. The electrical cable assembly of claim 1, wherein the metallized fabric body of the electrical cable shield comprises a fabric layer and a metal layer that extends on the fabric layer, the metal layer being fabricated from at least one of aluminum, steel, nickel, tin, or silver.

8. The electrical cable assembly of claim 1, wherein the first electrical connector comprises a fitting having a non-circular profile, the first shield end of the metallized fabric body being dressed over the non-circular profile of the fitting of the first electrical connector.

9. The electrical cable assembly of claim 1, wherein the metallized fabric body of the electrical cable shield extends around the electrical cable such that there is an air gap between the metallized fabric body and the electrical cable along at least a portion of the length of the electrical cable.

10. The electrical cable assembly of claim 1, wherein the electrical cable shield is a first electrical cable shield, the electrical cable comprising at least one of a second electrical cable shield that extends around the at least one electrical wire or an electrically insulative jacket that extends around the at least one electrical wire, the first electrical cable shield extending around the at least one of the second electrical cable shield or the electrically insulative jacket.

11. The electrical cable assembly of claim 1, wherein at least one of the first shield end of the metallized fabric body is dressed over the first electrical connector such that the metallized fabric body is electrically connected to the first electrical connector or the second shield end of the metallized fabric body is dressed over the second electrical connector such that the metallized fabric body is electrically connected to the second electrical connector.

12. An electrical cable assembly comprising:
an electrical cable extending a length from a first cable end to an opposite second cable end, the electrical cable comprising at least one electrical wire;
an electrical cable shield comprising a metallized fabric body that extends around the electrical cable along the length of the electrical cable between the first and second cable ends, the metallized fabric body extending a length along the length of the electrical cable from a first shield end to a second shield end of the metallized fabric body, the metallized fabric body having opposite first and second edges that extend along the length of the metallized fabric body from the first shield end to the second shield end, wherein the first and second edges are sewed together with an electrically conductive thread.

13. The electrical cable assembly of claim 12, wherein the electrically conductive thread is fabricated from at least one of aluminum, steel, nickel, tin, or silver.

14. The electrical cable assembly of claim 12, wherein the metallized fabric body of the electrical cable shield comprises a fabric layer and a metal layer that extends on the fabric layer, the fabric layer being fabricated from at least one of nylon or polyester, the metal layer being fabricated from at least one of aluminum, steel, nickel, tin, or silver.

15. The electrical cable assembly of claim 12, wherein the metallized fabric body of the electrical cable shield extends around the electrical cable such that there is an air gap between the metallized fabric body and the electrical cable along at least a portion of the length of the electrical cable.

16. The electrical cable assembly of claim 12, further comprising a first electrical connector terminated to the first cable end of the electrical cable, and a second electrical connector terminated to the second cable end of the electrical cable, wherein the first shield end of the metallized fabric body is dressed over the first electrical connector, and wherein the second shield end of the metallized fabric body is dressed over the second electrical connector.

17. The electrical cable assembly of claim 12, further comprising a first electrical connector terminated to the first cable end of the electrical cable, and a second electrical connector terminated to the second cable end of the electrical cable, wherein the first shield end of the metallized fabric body is dressed over a first backshell of the first electrical connector, and wherein the second shield end of the metallized fabric body is dressed over a second backshell of the second electrical connector.

18. The electrical cable assembly of claim 12, further comprising a first electrical connector terminated to the first cable end of the electrical cable, and a second electrical connector terminated to the second cable end of the electrical cable, the first shield end of the metallized fabric body being dressed over the first electrical connector, the second shield end of the metallized fabric body being dressed over the second electrical connector, wherein at least one of the first shield end of the metallized fabric body is held on the first electrical connector or the second shield end of the metallized fabric body is held on the second electrical connector using at least one of a zip tie, a band, a rubber band, a heat recoverable ring, a clamp, a hose clamp, safety wire, or an adhesive.

19. The electrical cable assembly of claim 12, further comprising a first electrical connector terminated to the first cable end of the electrical cable, and a second electrical connector terminated to the second cable end of the electrical cable, wherein the first shield end of the metallized fabric body is dressed over a non-circular profile of the first electrical connector, and wherein the second shield end of the metallized fabric body is dressed over a non-circular profile of the second electrical connector.

20. An electrical cable assembly comprising:
an electrical cable extending a length from a first cable end to an opposite second cable end, the electrical cable comprising at least one electrical wire; and
an electrical cable shield comprising a metallized fabric body that extends around the electrical cable along the length of the electrical cable from the first cable end to the second cable end.
